(19) United States
(12) Patent Application Publication
(10) Pub. No.: US 2026/0002245 A1
(43) Pub. Date: Jan. 1, 2026

(54) MASK FOR MANUFACTURING DISPLAY PANEL, AND ELECTRONIC DEVICE HAVING THE DISPLAY PANEL

(71) Applicant: Samsung Display Co., LTD., Yongin-si (KR)

(72) Inventors: Jae Min HONG, Yongin-si (KR); Jin Woo PARK, Yongin-si (KR); Young Shin LEE, Yongin-si (KR)

(21) Appl. No.: 19/037,473

(22) Filed: Jan. 27, 2025

(30) Foreign Application Priority Data
Jun. 27, 2024 (KR) 10-2024-0084272

(51) Int. Cl. C23C 14/04; H10K 71/16

(52) U.S. Cl. CPC C23C 14/042; H10K 71/166

(57) ABSTRACT

A mask includes a first silicon nitride layer and a first reinforcing layer, where the first silicon nitride layer has a first pattern for deposition of a display panel. The first reinforcing layer is formed on the first silicon nitride layer and has a second pattern corresponding to the first pattern, where a brittleness of the first reinforcing layer is lower than a brittleness of the first silicon nitride layer.

The application claims priority to Korean Patent Application No. 10-2024-0084272, filed on Jun. 27, 2024, and all the benefits accruing therefrom under 35 U.S.C. § 119, the content of which in its entirety is herein incorporated by reference.

### BACKGROUND

### 1. Field

The present invention relates to a mask for manufacturing a display device, and an electronic device having the display device.

### 2. Description of Related Art

A display panel of a display device includes a plurality of pixels, where each of the pixels includes a driving element such as a transistor and a display element such as an organic light emitting element. The display element may be formed by laminating electrodes and various functional layers on a substrate.

The functional layers constituting the display element are provided through a patterning process using a mask having an open area defined to penetrate therethrough. In this case, the shape of the patterned functional layers may be controlled according to the shape of the open area of the mask, and the like. As the resolution of the display panel increases, patterns of the mask become finer and the thickness of the mask also decreases.

### SUMMARY

The present invention provides a mask having enhanced strength and which is used in a manufacturing process of a high-resolution display panel.

A mask, according to an embodiment, may include a first silicon nitride layer and a first reinforcing layer. The first silicon nitride layer may have a first pattern for deposition of a display panel. The first reinforcing layer may be formed on the first silicon nitride layer and may have a second pattern corresponding to the first pattern. A brittleness of the first reinforcing layer may be lower than a brittleness of the first silicon nitride layer.

In an embodiment, the mask may further include a base layer, where the base layer may be positioned below the first silicon nitride layer and may have a third pattern.

In an embodiment, the mask may further include a second reinforcing layer which may be formed below the first silicon nitride layer and may have a fourth pattern corresponding to the first pattern.

In an embodiment, the second reinforcing layer may be formed within an opening of the base layer. The opening of the base layer may be defined by the third pattern.

In an embodiment, the base layer may include silicon.

In an embodiment, the mask may further include a second silicon nitride layer formed below the base layer.

In an embodiment, the first reinforcing layer may include photosensitive polyimide.

In an embodiment, the first reinforcing layer may be formed by performing a curing process on a photosensitive polyimide layer. The second pattern may be formed on the photosensitive polyimide layer.

In an embodiment, a dimension of an opening defined by the second pattern may be larger than a dimension of an opening defined by the first pattern.

In an embodiment, an angle between an inner surface of the opening defined by the second pattern and a lower surface of the first reinforcing layer may be smaller than an angle between an inner surface of the opening defined by the first pattern and a lower surface of the first silicon nitride layer.

In an embodiment, a mask may include a base layer, a first silicon nitride layer, and a reinforcing layer. The base layer may have a first opening and the first silicon nitride layer may be formed on the base layer and may have a first pattern for deposition of a display panel. The reinforcing layer may be formed below the first silicon nitride layer within the first opening of the base layer and may have a second pattern corresponding to the first pattern. A brittleness of the reinforcing layer may be lower than a brittleness of the first silicon nitride layer.

In an embodiment, the base layer may include silicon.

In an embodiment, the mask may further include a second silicon nitride layer formed below the base layer.

In an embodiment, the reinforcing layer may include photosensitive polyimide.

In an embodiment, the reinforcing layer may be formed by performing a curing process on a photosensitive polyimide layer. The second pattern may be formed on the photosensitive polyimide layer.

In an embodiment, a dimension of an opening defined by the second pattern may be larger than a dimension of an opening defined by the first pattern.

In an embodiment, an angle between an inner surface of the opening defined by the second pattern and an upper surface of the reinforcing layer may be smaller than an angle between an inner surface of the opening defined by the first pattern and a lower surface of the first silicon nitride layer.

In an embodiment, the base layer may be positioned below the first silicon nitride layer and include a third pattern.

In an embodiment, an electronic device may include a display device having a display panel which includes a display element. The display element may include functional layers which are formed via a patterning process which uses a mask. The mask may include a first silicon nitride layer and a first reinforcing layer. The first silicon nitride layer may have a first pattern for deposition of a display panel. The first reinforcing layer may be formed on the first silicon nitride layer and may have a second pattern corresponding to the first pattern. A brittleness of the first reinforcing layer may be lower than a brittleness of the first silicon nitride layer.

In an embodiment, the mask may further include a base layer, where the base layer may be positioned below the first silicon nitride layer and may have a third pattern.

In an embodiment, the mask may further include a second reinforcing layer which may be formed below the first silicon nitride layer and may have a fourth pattern corresponding to the first pattern.

In an embodiment, the second reinforcing layer may be formed within an opening of the base layer. The opening of the base layer may be defined by the third pattern.

In an embodiment, the base layer may include silicon.

In an embodiment, the mask may further include a second silicon nitride layer formed below the base layer.

In an embodiment, the first reinforcing layer may include photosensitive polyimide.

In an embodiment, the first reinforcing layer may be formed by performing a curing process on a photosensitive polyimide layer. on which Thethe second pattern is may be formed on the photosensitive polyimide layer.

In an embodiment, a dimension of an opening defined by the second pattern may be larger than a dimension of an opening defined by the first pattern.

In an embodiment, an angle between an inner surface of the opening defined by the second pattern and a lower surface of the first reinforcing layer may be smaller than an angle between an inner surface of the opening defined by the first pattern and a lower surface of the first silicon nitride layer.

### BRIEF DESCRIPTION OF THE DRAWINGS

The accompanying drawings, which are included to provide a further understanding of the invention and which are incorporated in and constitute a part of this specification, illustrate exemplary embodiments of the invention, and, together with the description, serve to explain principles of the invention.

FIG. 1 is a cross-sectional view of a deposition apparatus, according to an embodiment.

FIG. 2 is a plan view of a display panel formed through the deposition apparatus, according to an embodiment.

FIG. 3 is a cross-sectional view of the display panel of FIG. 2 taken along line I-I′, according to an embodiment.

FIG. 4 is an exploded perspective view illustrating an example of a mask assembly including a mask and a mask frame, according to an embodiment.

FIG. 5A is a cross-sectional view illustrating a process for manufacturing a mask, according to an embodiment.

FIG. 5B is a cross-sectional view illustrating a process for manufacturing a mask, according to an embodiment.

FIG. 5C is a cross-sectional view illustrating a process for manufacturing a mask, according to an embodiment.

FIG. 5D is a cross-sectional view illustrating a process for manufacturing a mask, according to an embodiment.

FIG. 5E is a cross-sectional view illustrating a process for manufacturing a mask, according to an embodiment.

FIG. 5F is a cross-sectional view illustrating a process for manufacturing a mask, according to an embodiment.

FIG. 5G is a cross-sectional view illustrating a process for manufacturing a mask, according to an embodiment.

FIG. 5H is a cross-sectional view illustrating a process for manufacturing a mask, according to an embodiment.

FIG. 5I is a cross-sectional view illustrating a process for manufacturing a mask, according to an embodiment.

FIG. 5J is a cross-sectional view illustrating a process for manufacturing a mask, according to an embodiment.

FIG. 6A is a cross-sectional view illustrating a process for manufacturing a mask, according to another embodiment.

FIG. 6B is a cross-sectional view illustrating a process step for manufacturing a mask, according to another embodiment.

FIG. 6C is a cross-sectional view illustrating a process step for manufacturing a mask, according to another embodiment.

FIG. 6D is a cross-sectional view illustrating a process step for manufacturing a mask, according to another embodiment.

FIG. 6E is a cross-sectional view illustrating a process step for manufacturing a mask, according to another embodiment.

FIG. 6F is a cross-sectional view illustrating a process step for manufacturing a mask, according to another embodiment.

FIG. 6G is a cross-sectional view illustrating a process step for manufacturing a mask, according to another embodiment.

FIG. 6H is a cross-sectional view illustrating a process step for manufacturing a mask, according to another embodiment.

FIG. 6I is a cross-sectional view illustrating a process step for manufacturing a mask, according to another embodiment.

FIG. 6J is a cross-sectional view illustrating a process step for manufacturing a mask, according to another embodiment.

FIG. 6K is a cross-sectional view illustrating a process step for manufacturing a mask, according to another embodiment.

FIG. 7A is a diagram illustrating an example of an area A in FIG. 6K in more detail, according to an embodiment.

FIG. 7B is a diagram illustrating an example of an area A in FIG. 6K in more detail, according to an embodiment.

FIG. 8A is a cross-sectional view illustrating a process for manufacturing a mask, according to still another embodiment.

FIG. 8B is a cross-sectional view illustrating a process step for manufacturing a mask, according to still another embodiment.

FIG. 8C is a cross-sectional view illustrating a process step for manufacturing a mask, according to still another embodiment.

FIG. 8D is a cross-sectional view illustrating a process step for manufacturing a mask, according to still another embodiment.

FIG. 8E is a cross-sectional view illustrating a process step for manufacturing a mask, according to still another embodiment.

FIG. 8F is a cross-sectional view illustrating a process step for manufacturing a mask, according to still another embodiment.

FIG. 8G is a cross-sectional view illustrating a process step for manufacturing a mask, according to still another embodiment.

FIG. 8H is a cross-sectional view illustrating a process step for manufacturing a mask, according to still another embodiment.

FIG. 8I is a cross-sectional view illustrating a process step for manufacturing a mask, according to still another embodiment.

FIG. 8J is a cross-sectional view illustrating a process step for manufacturing a mask, according to still another embodiment.

FIG. 8K is a cross-sectional view illustrating a process step for manufacturing a mask, according to still another embodiment.

FIG. 8L is a cross-sectional view illustrating a process step for manufacturing a mask, according to still another embodiment.

FIG. 9A is a cross-sectional view illustrating a process step for manufacturing a mask, according to still another embodiment.

FIG. 9B is a cross-sectional view illustrating a process step for manufacturing a mask, according to still another embodiment.

FIG. 9C is a cross-sectional view illustrating a process step for manufacturing a mask, according to still another embodiment.

FIG. 9D is a cross-sectional view illustrating a process step for manufacturing a mask, according to still another embodiment.

FIG. 9E is a cross-sectional view illustrating a process step for manufacturing a mask, according to still another embodiment.

FIG. 9F is a cross-sectional view illustrating a process step for manufacturing a mask, according to still another embodiment.

FIG. 9G is a cross-sectional view illustrating a process step for manufacturing a mask, according to still another embodiment.

FIG. 9H is a cross-sectional view illustrating a process step for manufacturing a mask, according to still another embodiment.

FIG. 9I is a cross-sectional view illustrating a process step for manufacturing a mask, according to still another embodiment.

FIG. 9J is a cross-sectional view illustrating a process step for manufacturing a mask, according to still another embodiment.

FIG. 9K is a cross-sectional view illustrating a process step for manufacturing a mask, according to still another embodiment.

FIG. 9L is a cross-sectional view illustrating a process step for manufacturing a mask, according to still another embodiment.

FIG. 10 is a block diagram of an electronic device according to an embodiment.

FIG. 11 shows schematic views of various embodiments of an electronic device.

### DETAILED DESCRIPTION

Hereinafter, various embodiments of the invention will be described in detail with reference to the accompanying drawings so that those of ordinary skill in the art may easily implement the invention. The invention may be embodied in various different forms and is not limited to the embodiments described herein.

In order to clearly describe the invention, parts that are not related to the description are omitted, and the same or similar components are denoted by the same reference numerals throughout the specification. Therefore, the reference numerals described above may also be used in other drawings.

In addition, the size and thickness of each component shown in the drawings are arbitrarily shown for convenience of description, and thus the invention is not limited to those shown in the drawings. In the drawings, thicknesses may be exaggerated to clearly express the layers and regions.

In addition, in the description, the expression “is the same” may mean “substantially the same”. That is, it may be the same enough to convince those of ordinary skill in the art to be the same. In other expressions, “substantially” may be omitted.

Throughout the specification, when it is described that an element is “connected” to another element, this includes not only being “directly connected”, but also being “indirectly connected” to each other with still another element interposed therebetween. The terms used herein are for the purpose of describing specific embodiments and are not intended to limit the scope of the invention. Throughout the specification, unless specifically described to the contrary, the word “include” and variations such as “includes” or “including” will be understood to imply the inclusion of stated elements but not the exclusion of any other elements. The terms “at least one of X, Y, and Z” and “at least one selected from the group consisting of X, Y, and Z” may be construed as X only, Y only, Z only, or any combination of two or more of X, Y, and Z (e.g., XYZ, XYY, YZ, and ZZ). As used herein, the term “and/or” includes any one or all combinations of one or more of corresponding configurations.

Although the terms “first, second, and so on” may be used herein to describe various constituent elements, these constituent elements should not be limited by these terms. These terms are used to distinguish one constituent element from another. Thus, a first constituent element discussed below can be called a second constituent element without departing from the teachings of the invention.

Spatially relative terms, such as “under,” “above,” and the like, may be used herein for descriptive purposes, and, thereby, to describe relationships between one element or a feature and other element(s) or feature(s) as illustrated in the drawings. Spatially relative terms are intended to encompass different directions of a device when in use, operation, and/or manufacture in addition to the direction depicted in the drawings. For example, if the device in the drawings is turned over, elements described to be located “under” other elements or features are located in a direction “above” the other elements or features. Accordingly, the term “under” may include both directions of the “above” and “under.” Furthermore, the device may be otherwise directed in different directions (e.g., rotated by 90 degrees or in different directions), and thus the spatially relative terms used herein are interpreted accordingly.

Various embodiments are described herein with reference to the drawings that are schematic illustrations of ideal embodiments. Accordingly, it will be expected that the shapes of the illustrations can be changed in accordance with the scope of the invention, for example, tolerances and/or manufacturing technologies. Thus, the embodiments disclosed herein should not be construed as being limited to the illustrated specific shapes but should be construed to include variations in shapes that result from, for example, manufacturing. As described above, the shapes illustrated in the drawings may not be intended to illustrate the actual shapes of areas of the device, and the invention is not limited thereto.

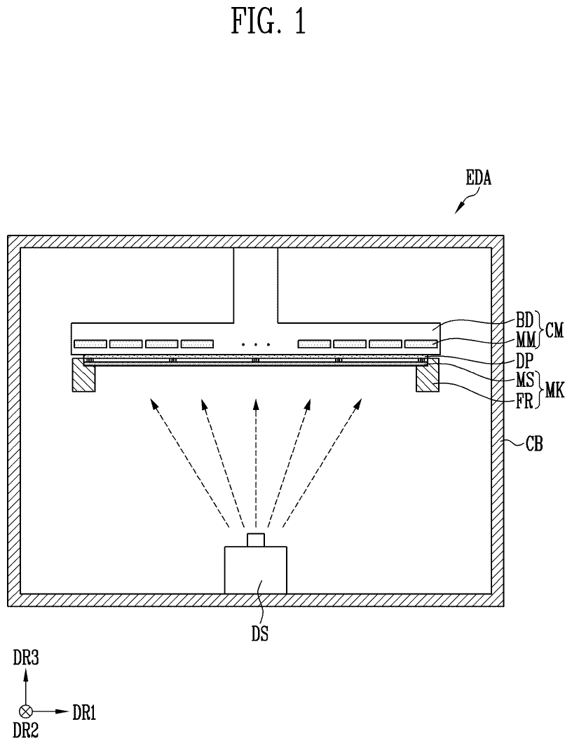

FIG. 1 is a cross-sectional view of a deposition apparatus, according to an embodiment.

In an embodiment and referring to FIG. 1, a deposition apparatus EDA may include a deposition chamber CB, a fixing member CM, a deposition source DS disposed inside the deposition chamber CB, and a mask assembly MK disposed inside the deposition chamber CB. Although not shown separately, the deposition apparatus EDA may further include a mechanical device for implementing an inline system.

In an embodiment, the deposition chamber CB may be set to vacuum deposition conditions and may include a bottom surface, a ceiling surface, and side walls. The bottom surface of the deposition chamber CB may be directed parallel to a plane defined by a first direction DR1 and a second direction DR2. A normal direction to the bottom surface of the deposition chamber CB may be indicated as a third direction DR3.

In an embodiment, the fixing member CM may be disposed inside the deposition chamber CB, may be disposed above the deposition source DS, and may fix the mask assembly MK. The fixing member CM may be installed on the ceiling surface of the deposition chamber CB and may include a jig or a robot arm that holds the mask assembly MK.

In an embodiment, the fixing member CM may include a support member BD and magnetic bodies MM coupled to the support member BD. The support member BD may include a plate as a basic structure for fixing the mask assembly MK, but the invention is not limited thereto. The magnetic bodies MM may be disposed inside or outside the support member BD and may fix the mask assembly MK with magnetic force.

In an embodiment, the deposition source DS may evaporate a deposition material so that the deposition vapor is discharged. The deposition vapor may pass through the mask assembly MK and may be deposited on a display panel DP in a predetermined pattern. The display panel DP may be defined as a substrate in an intermediate process for manufacturing the completed display panel DP to be described later.

In an embodiment, the mask assembly MK may be disposed inside the deposition chamber CB, may be disposed above the deposition source DS, and may support the display panel DP. The display panel DP may include a glass substrate or a plastic substrate, where the display panel DP may include a polymer layer disposed on a base substrate.

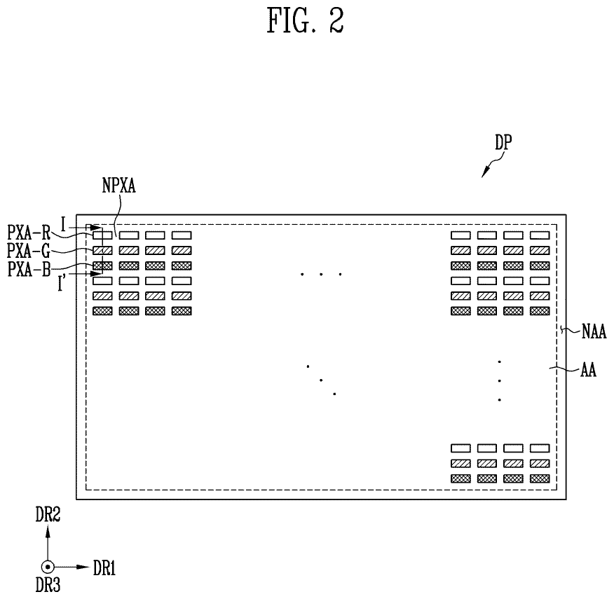

FIG. 2 is a plan view of a display panel formed through the deposition apparatus, according to an embodiment. More specifically, FIG. 2 is a plan view of the display panel DP manufactured through the deposition apparatus EDA (see FIG. 1), according to an embodiment. A deposition process may be performed while a plurality of display panels DP are disposed on the mask assembly MK shown in FIG. 1.

In an embodiment and referring to FIG. 2, the display panel DP may include an active area AA and a peripheral area NAA. The display panel DP may include a first light emitting area PXA-R, a second light emitting area PXA-G, and a third light emitting area PXA-B which are distinct from each other within the active area AA. For example, the first light emitting area PXA-R may be a red light emitting area that emits red light, the second light emitting area PXA-G may be a green light emitting area that emits green light, and the third light emitting area PXA-B may be a blue light emitting area that emits blue light.

In an embodiment, the light emitting areas PXA-R, PXA-G, and PXA-B may not overlap each other and may be distinct from each other when viewed on a plane defined by the first direction DR1 and the second direction DR2. An area between adjacent light emitting areas PXA-R, PXA-G, and PXA-B may be defined as a non-light emitting area NPXA.

In an embodiment, the display panel DP shown in FIGS. 1 and 2 may include at least one functional layer manufactured using a mask MS. For example, a functional layer in the form of a ‘common layer’ that is provided to overlap with all of a plurality of light emitting areas PXA-R, PXA-G, and PXA-B among functional layers included in the display panel DP may be provided using the mask MS, according to the an embodiment.

According to an embodiment, the light emitting areas PXA-R, PXA-G, and PXA-B of the display panel DP may be arranged in a stripe shape. That is, a plurality of first light emitting areas PXA-R, a plurality of second light emitting areas PXA-G, and a plurality of third light emitting areas PXA-B may be arranged alternately along the first direction DR1, and light emitting areas that provide light of the same color may be arranged to be spaced apart from each other along the second direction DR2.

In an embodiment, an arrangement form of the light emitting areas PXA-R, PXA-G, and PXA-B is not limited thereto, and the order in which the first light emitting area PXA-R, the second light emitting area PXA-G, and the third light emitting area PXA-B are arranged may be provided in various combinations depending on the characteristics of the display quality required by the display panel DP.

For example, in an embodiment, the light emitting areas PXA-R, PXA-G, and PXA-B may have a PENTILE™ structure in the form of a diamond array. In addition, areas of the light emitting areas PXA-R, PXA-G, and PXA-B may also be different from each other, and the arrangement form and area may be adjusted or modified in variously ways according to the characteristics of the display quality required by the display panel DP.

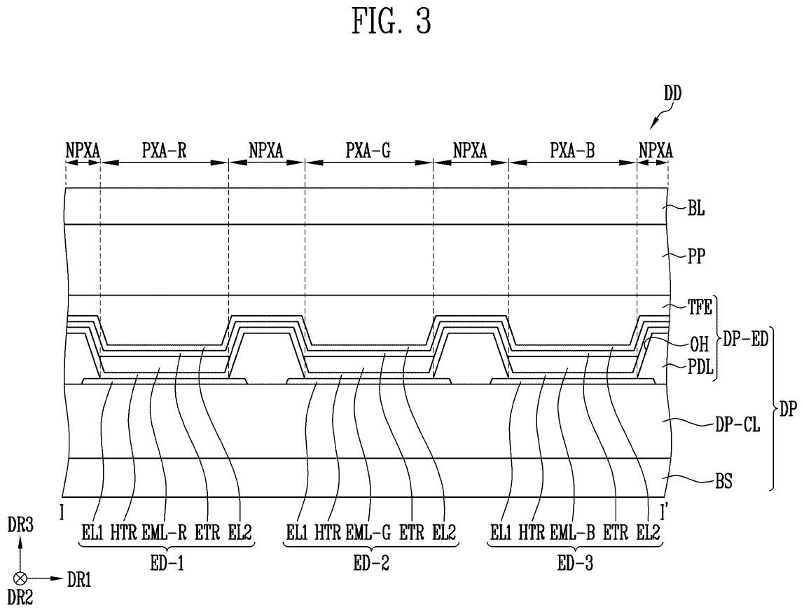

FIG. 3 is a cross-sectional view taken along line I-I′ in FIG. 2, according to an embodiment.

In an embodiment and referring to FIG. 3, the display panel DP formed through the deposition apparatus EDA (see FIG. 1) may be combined with an optical layer PP and a cover substrate BL disposed on the display panel DP to constitute a display device DD. The display panel DP may include a plurality of light emitting elements ED-1, ED-2, and ED-3. The optical layer PP may be disposed on the display panel DP to control light reflected on the display panel DP due to external light. The optical layer PP may include, for example, a polarizing layer or a color filter layer. In another embodiment, the optical layer PP may be omitted in the display device DD.

In an embodiment, the cover substrate BL may be disposed on the optical layer PP, where the cover substrate BL may be a member that provides a base surface on which the optical layer PP is disposed. The cover substrate BL may be an inorganic layer, an organic layer, or a composite material layer. In addition, unlike as shown in the drawing, in one embodiment, the cover substrate BL may be omitted.

In an embodiment, the display panel DP may include a base layer BS, a circuit layer DP-CL provided on the base layer BS, and a display element layer DP-ED. The display element layer DP-ED may include the light emitting elements ED-1, ED-2, and ED-3. In addition, the display panel DP may include an encapsulation layer TFE disposed on the display element layer DP-ED.

In an embodiment, the display panel DP may be an organic electroluminescence display panel including an organic electroluminescence element in the display element layer DP-ED. That is, the mask MS (see FIG. 1) may be used when forming a part of the functional layer of the display element layer DP-ED of the organic electroluminescence display panel.

In an embodiment, the circuit layer DP-CL may be disposed on the base layer BS, and the circuit layer DP-CL may include a plurality of transistors (not shown), where each of the transistors (not shown) may include a control electrode, an input electrode, and an output electrode. In addition, the circuit layer DP-CL may include a plurality of insulating layers.

In an embodiment, the encapsulation layer TFE may cover the light emitting elements ED-1, ED-2, and ED-3 and may seal the display element layer DP-ED. The encapsulation layer TFE may be a thin film encapsulation layer.

In an embodiment, each of the light emitting elements ED-1, ED-2, and ED-3 may include a first electrode EL1, a hole transport region HTR, a light emitting layer EML-R, EML-G, or EML-B, an electron transport region ETR, and a second electrode EL2.

In an embodiment, the first electrode EL1 of each of the light emitting elements ED-1, ED-2, and ED-3 may be exposed at least in part through a display opening OH defined by a pixel defining layer PDL. The light emitting layer EML-R, EML-G, or EML-B may be disposed within the display opening OH, and the hole transport region HTR, the electron transport region ETR, and the second electrode EL2 may be provided as common layers throughout the light emitting elements ED-1, ED-2, and ED-3.

In an embodiment, at least one of the hole transport region HTR, the electron transport region ETR, and the second electrode EL2 provided as common layers in the light emitting elements ED-1, ED-2, and ED-3 of the display panel DP may be provided using the mask MS of the present invention.

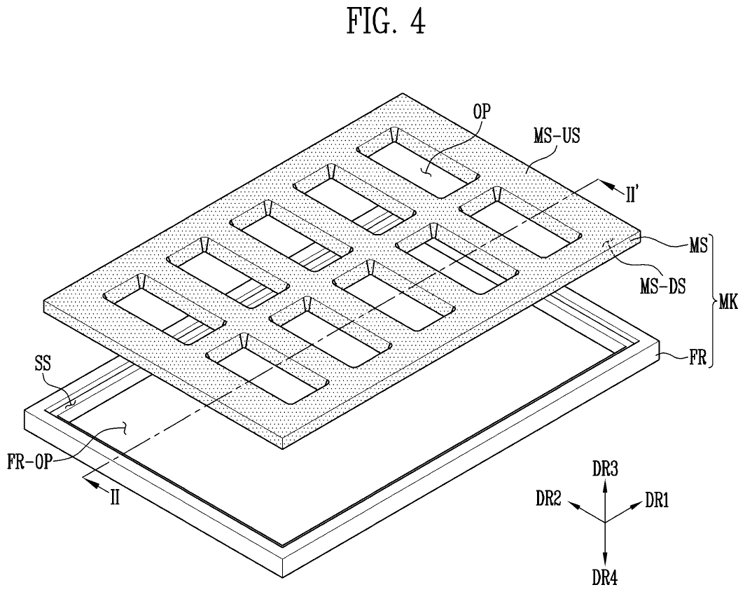

Meanwhile, some of insulating layers included in the circuit layer DP-CL or the encapsulation layer TFE disposed on the light emitting elements ED-1, ED-2, and ED-3 may also be provided using the mask MS (See FIG. 1 and FIG. 4).

FIG. 4 is an exploded perspective view illustrating an example of a mask assembly including a mask and a mask frame, according to an embodiment. In FIG. 4, a direction that is directed opposite to the first direction DR1 may be defined as a fourth direction DR4.

In an embodiment and referring to FIG. 4, the mask assembly MK may include the mask MS and a mask frame FR. In an embodiment, the mask assembly MK may be used to form a common layer including the same material on a target substrate, which is a deposition surface. In an embodiment, the mask assembly MK may include an open mask for a thin film process used to form the functional layer provided as a thin film, where the open mask for a thin film process may be a mask used to laminate a thin film layer of the same material across a single display device on the target substrate.

In an embodiment, the mask frame FR may support the mask MS. For example, the mask frame FR may have a frame opening FR-OP defined on the inside of the mask frame FR, and the mask MS may be disposed within the frame opening FR-OP. More specifically, the mask frame FR may have an upper surface and a lower surface that are directed perpendicular to the third direction DR3. Meanwhile, the frame opening may be defined by a plurality of inner surfaces that are directed perpendicular to the upper surface. The plurality of inner surfaces defining the frame opening may also be directed perpendicular to the lower surface.

In an embodiment, the mask frame FR may support an edge portion of the mask MS. In an embodiment, the mask frame FR may be disposed under the mask MS, where the mask MS may be mounted on the mask frame FR. For example, the mask frame FR may include a support surface SS that supports the mask MS on the inside where the frame opening FR-OP is defined, and the mask MS may be disposed on the support surface SS. However, the invention is not limited thereto. The mask frame FR may be disposed on edges of upper and lower surfaces of the mask MS to support the mask MS. In another embodiment, the mask MS may be fixed to the mask frame FR. In an embodiment, the mask frame FR may be formed of a metal material including at least one of iron (Fe) and nickel (Ni). For example, the mask frame FR may include an alloy of iron and nickel. The mask frame FR may be manufactured to include stainless steel (SUS), Invar, or the like.

In an embodiment, the mask MS may include at least one open area OP. In an embodiment, the mask MS may include a plurality of open areas OP spaced apart from each other when viewed on a plane.

In an embodiment, the plurality of open areas OP may be defined to be aligned on a plane defined by a first direction axis DR1 and a second direction axis DR2. FIG. 4 shows an embodiment of the mask MS in which five open areas OP are defined and are spaced apart from each other along the first direction axis DR1 and in which two open areas OP are defined and are spaced apart from each other along the second direction axis DR2. However, this is only an example, and the number of open areas OP is not limited to that shown in the drawing. The open areas OP may be arranged to have a constant separation interval along one of the first direction axis DR1 and the second direction axis DR2. In an embodiment, a material for forming the functional layer in the form of a common layer may be deposited onto the target substrate through each of the plurality of open areas OP.

According to an embodiment, the mask MS may have a plate shape extending along the first direction axis DR1 and the second direction axis DR2. In an embodiment, the mask MS may have a square shape when viewed on a plane defined by the first direction axis DR1 and the second direction axis DR2. However, of the invention is not limited thereto. In an embodiment, the shape of the mask MS may be provided in a different form depending on the shape of the target substrate, which is the deposition surface, the shape of the mask frame FR that supports the mask MS, or the like.

In addition, in the mask MS, according to an embodiment, the open areas OP may have a square shape when viewed on a plane. However, the invention is not limited thereto. Accordingly, in an embodiment, the shape of the open areas MC may be modified to have various shapes depending on the shape of functional layers formed by deposited on the target substrate.

In an embodiment, the mask MS may include a lower surface (or first surface) MS-DS and an upper surface (or second surface) MS-US facing each other.

In an embodiment, the mask MS may include a silicon nitride (SiN) thin film, where the silicon nitride thin film may be formed through a chemical vapor deposition process such as plasma enhanced chemical vapor deposition (PECVD), low pressure chemical vapor deposition (LPCVD), or low temperature chemical vapor deposition (LTCVD).

In an embodiment, the silicon nitride thin film may have relatively high hardness, and thus may act as a membrane. In addition, the silicon nitride thin film may be applied to both sides of a wafer because they have high heat resistance and oxidation resistance.

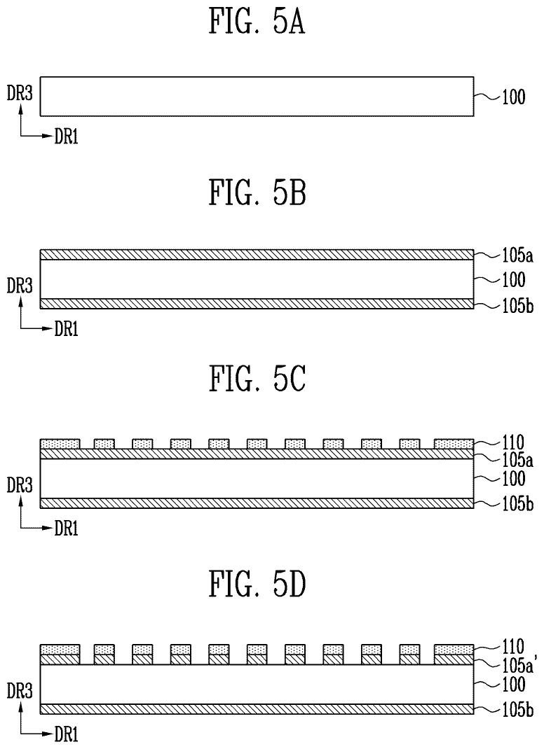

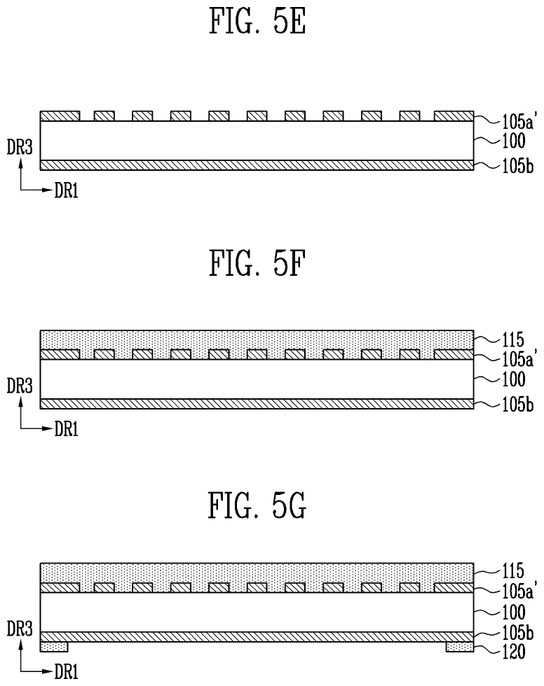

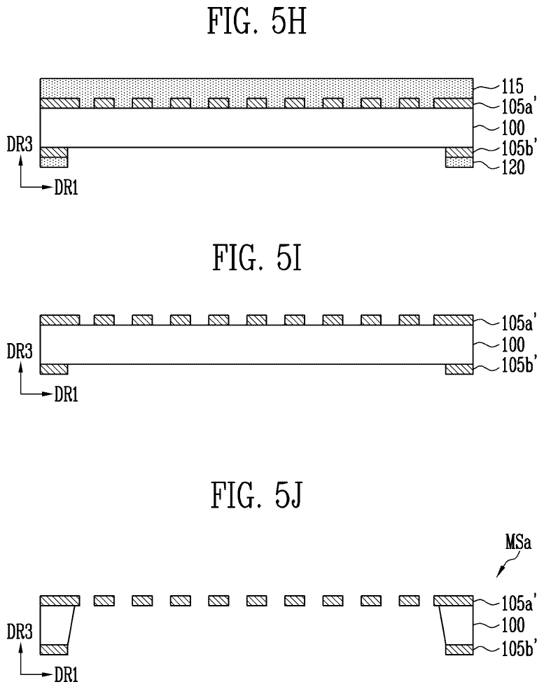

FIGS. 5A to 5J are cross-sectional views illustrating a process for manufacturing a mask, according to an embodiment.

In an embodiment and referring to FIG. 5A and FIG. 5B, a base layer 100 may be provided for manufacturing a mask MS, where the base layer 100 may include silicon and may be provided in the form of a silicon wafer. Referring to FIG. 5B, a first silicon nitride layer 105a may be formed on an upper surface of the base layer 100, and a second silicon nitride layer 105b may be formed on a lower surface of the base layer 100. The silicon nitride layers 105a and 105b may be formed on the upper and lower surfaces of the base layer 100 through a process such as plasma enhanced chemical vapor deposition (PECVD), low pressure chemical vapor deposition (LPCVD), or low temperature chemical vapor deposition (LTCVD).

In an embodiment and referring to FIG. 5C, a photosensitive layer 110 may be formed on the first silicon nitride layer 105a, where the photosensitive layer 110 may be formed to correspond to a pattern that the mask MS will ultimately have. A photolithography process may be applied to form the photosensitive layer 110 of FIG. 5C. That is, a photosensitive agent (photoresist) may be applied on the first silicon nitride layer 105a, and a pattern corresponding to the mask MS may be formed on the photosensitive agent through an exposure process. Thereafter, the photosensitive layer 110 may be formed by removing unnecessary portions of the photosensitive agent using a developer. In addition, a hard bake process may be performed on the photosensitive layer 110 for a subsequent etching process.

Thereafter, in an embodiment, an etching process may be performed on the first silicon nitride layer 105a of FIG. 5C. Through the etching process, a pattern corresponding to the pattern of the photosensitive layer 110 may be formed on the first silicon nitride layer 105a. In an embodiment and referring to FIG. 5D, a first silicon nitride layer 105a′ having a pattern through the etching process is shown. In an embodiment, a dry etching process may be applied to form a fine pattern.

In an embodiment and referring to FIG. 5E, the photosensitive layer 110 on the first silicon nitride layer 105a′ having the pattern may be removed. In an embodiment, the photosensitive layer 110 may be removed using a developer. Accordingly, the first silicon nitride layer 105a′ having the pattern may be exposed.

In an embodiment and referring to FIG. 5F, a protective layer 115 may be formed on the first silicon nitride layer 105a′ having the pattern. In an embodiment, a photosensitive solution may be coated on the first silicon nitride layer 105a′ having the pattern to form the protective layer 115. As the protective layer 115 is formed, the first silicon nitride layer 105a′ having the pattern on the upper surface of the base layer 100 can be protected.

In an embodiment and referring to FIG. 5G, a photosensitive layer 120 may be formed under the second silicon nitride layer 105b, where the photosensitive layer 120 of FIG. 5G may be formed in the same manner as the photosensitive layer 110 described with reference to FIG. 5C. The photosensitive layer 120 of FIG. 5G may be formed to have a pattern corresponding to an edge of the mask MS. A photolithography process may be applied to form the photosensitive layer 120 of FIG. 5G. Since the photolithography process has been described with reference to FIG. 5C, a redundant description will be omitted. Thereafter, an etching process may be performed on the second silicon nitride layer 105b of FIG. 5G. Through the etching process, a pattern corresponding to the pattern of the photosensitive layer 120 may be formed on the second silicon nitride layer 105b.

In an embodiment and referring to FIG. 5H, a second silicon nitride layer 105b′ having a pattern through the etching process is shown.

In an embodiment and referring to FIG. 5I, the photosensitive layer 120 disposed under the second silicon nitride layer 105b′ having the pattern may be removed. In an embodiment, the photosensitive layer 120 may be removed using a developer. Accordingly, the second silicon nitride layer 105b′ having the pattern may be exposed. Meanwhile, in this process, the protective layer 115 on the first silicon nitride layer 105a′ having the pattern may be removed. Accordingly, the first silicon nitride layer 105a′ having the pattern may be exposed.

In an embodiment and referring to FIG. 5J, unnecessary portions of the base layer 100 may be removed. That is, portions of the base layer 100 exposed by openings of the silicon nitride layers 105a′ and 105b′ having patterns may be etched and removed. In an embodiment, a tetramethyl ammonium hydroxide (TMAH) solution may be used to etch the base layer 100 formed of a silicon wafer. The TMAH may be a strong alkaline organic substance and may be used as a corrosive agent for silicon materials. By removing unnecessary portions of the base layer 100, a mask MSa may be finally completed. The mask MSa shown in FIG. 5J may be an embodiment of the mask MS shown in FIG. 4. More specifically, FIG. 5J may be a cross-sectional view corresponding to line II-II′ in FIG. 4. However, in FIG. 5J, only the mask of FIG. 4 is shown, and the mask frame is omitted.

In an embodiment and referring again to FIG. 5J, a single layer of silicon nitride may be used as a thin film forming the pattern of the mask MSa. When the thickness of a film on which the pattern is formed is thick, it may be difficult to form a fine pattern on the display panel. That is, as the resolution of the display panel increases, the pattern of the mask MSa becomes finer, and at the same time, the thickness of the first silicon nitride layer 105a′ having the pattern needs to be reduced. Since the brittleness of the silicon nitride thin film is relatively high, the risk of the mask MSa being damaged may increase as the thickness of the first silicon nitride layer 105a′ decreases. Therefore, when manufacturing a mask for manufacturing a high-resolution display panel, there is a need to increase the durability of the silicon nitride thin film.

According to a mask of another embodiment, a reinforcing layer may be formed on an upper or lower surface of a silicon nitride layer on which a pattern is formed. Accordingly, the possibility of damage to the mask MSa can be reduced.

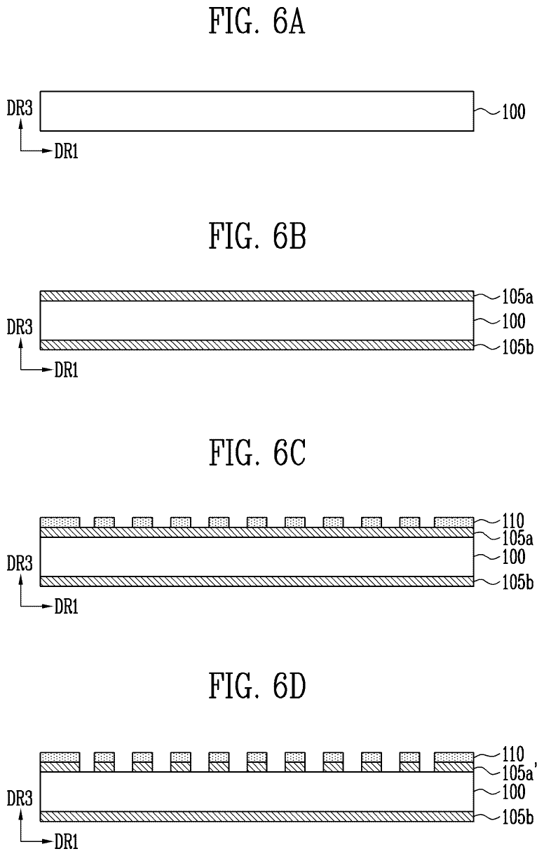

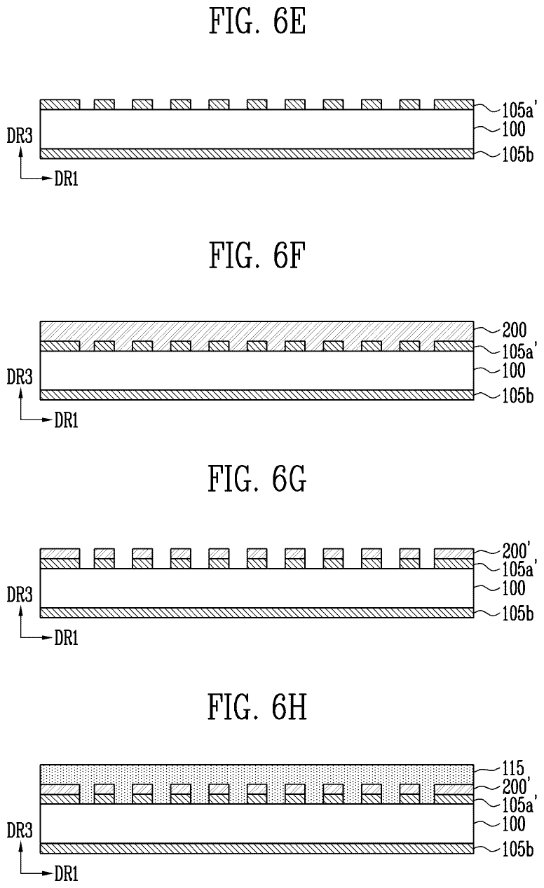

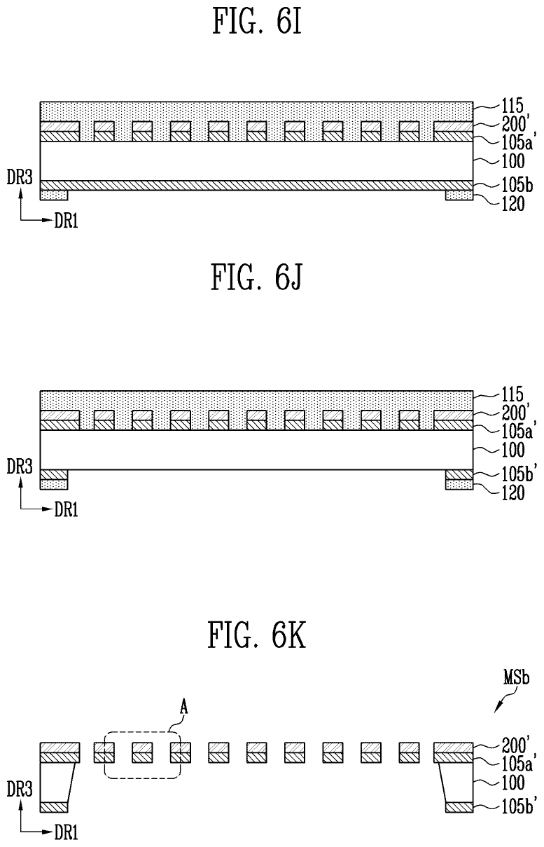

FIGS. 6A to 6K are cross-sectional views illustrating a process for manufacturing a mask, according to another embodiment. Hereinafter, descriptions of content that overlaps with those described with reference to FIGS. 5A to 5J will be omitted.

In an embodiment and referring to FIG. 6A and FIG. 6B, a base layer 100 may be provided for manufacturing a mask MS. In an embodiment, the base layer 100 may be provided in the form of a silicon wafer. Referring to FIG. 6B, a first silicon nitride layer 105a may be formed on an upper surface of the base layer 100, and a second silicon nitride layer 105b may be formed on a lower surface of the base layer 100.

In an embodiment and referring to FIG. 6C, a photosensitive layer 110 may be formed on the first silicon nitride layer 105a, where the photosensitive layer 110 may be formed to correspond to a pattern that the mask MS will ultimately have. A photolithography process may be applied to form the photosensitive layer 110 of FIG. 6C.

Thereafter, in an embodiment, an etching process may be performed on the first silicon nitride layer 105a of FIG. 6C. Through the etching process, a pattern corresponding to the pattern of the photosensitive layer 110 may be formed on the first silicon nitride layer 105a. In an embodiment and referring to FIG. 6D, a first silicon nitride layer 105a′ having a pattern through the etching process is shown. In an embodiment, a dry etching process may be applied to form a fine pattern.

In an embodiment and referring to FIG. 6E, the photosensitive layer 110 on the first silicon nitride layer 105a′ having the pattern may be removed. Accordingly, the first silicon nitride layer 105a′ having the pattern may be exposed.

In an embodiment and referring to FIG. 6F, a reinforcing layer 200 may be formed on the first silicon nitride layer 105a′ having the pattern. In an embodiment, the brittleness of a material forming the reinforcing layer 200 may be lower than the brittleness of a material forming the first silicon nitride layer 105a′. For example, the reinforcing layer 200 may include photosensitive polyimide (PSPI). However, this is only an example, and the material forming the reinforcing layer 200 may be selected from materials having lower brittleness than the first silicon nitride layer 105a′ having the pattern, other than photosensitive polyimide.

Thereafter, in an embodiment, a reinforcing layer 200′ having a pattern as shown in FIG. 6G may be formed by selectively etching the reinforcing layer 200 using the photolithography process as described with reference to FIGS. 6C to 6E. When the reinforcing layer 200 is composed of photosensitive polyimide, a process of curing the reinforcing layer 200′ having the pattern may be selectively performed.

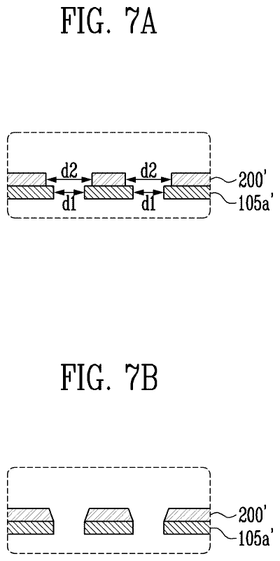

In an embodiment, the pattern of the reinforcing layer 200′ may be substantially the same as the pattern of the first silicon nitride layer 105a′. However, since the reinforcing layer 200′ is added on the first silicon nitride layer 105a′, it may be disadvantageous to apply a fine process when manufacturing the display panel. To address this, in an embodiment, a dimension of an opening defined by the pattern of the reinforcing layer 200′ may be larger than a dimension of an opening defined by the pattern of the first silicon nitride layer 105a′. This will be described later with reference to FIG. 7A.

In another embodiment, in the cross-sectional view, an angle between an inner surface of the opening defined by the pattern of the reinforcing layer 200′ and a lower surface of the reinforcing layer 200′ may be smaller than an angle between an inner surface of the opening defined by the pattern of the first silicon nitride layer 105a′ and a lower surface of the first silicon nitride layer 105a′. This will be described later with reference to FIG. 7B.

Thereafter, in an embodiment and referring to FIG. 6H, a protective layer 115 may be formed on the first silicon nitride layer 105a′ and the reinforcing layer 200′. In an embodiment, a photosensitive solution may be coated on the first silicon nitride layer 105a′ having the pattern and the reinforcing layer 200′ to form the protective layer 115. As the protective layer 115 is formed, the first silicon nitride layer 105a′ and the reinforcing layer 200′ can be protected.

In an embodiment and referring to FIG. 6I, a photosensitive layer 120 may be formed under the second silicon nitride layer 105b. As described above, the photosensitive layer 120 of FIG. 6I may be formed to have a pattern corresponding to an edge of the mask MS. A photolithography process may be applied to form the photosensitive layer 120 of FIG. 6I.

Thereafter, an etching process may be performed on the second silicon nitride layer 105b of FIG. 6I. Through the etching process, a pattern corresponding to the pattern of the photosensitive layer 120 may be formed on the second silicon nitride layer 105b. In an embodiment and referring to FIG. 6J, a second silicon nitride layer 105b′ having a pattern through the etching process is shown.

In an embodiment and referring to FIG. 6K, the photosensitive layer 120 under the second silicon nitride layer 105b′ having the pattern may be removed. In an embodiment, the photosensitive layer 120 may be removed using a developer. Accordingly, the second silicon nitride layer 105b′ having the pattern may be exposed. Meanwhile, in this process, the protective layer 115 on the first silicon nitride layer 105a′ having the pattern and the reinforcing layer 200′ may be removed. Accordingly, the first silicon nitride layer 105a′ having the pattern and the reinforcing layer 200′ may be exposed. Meanwhile, referring to FIG. 6K, unnecessary portions of the base layer 100 may be removed. That is, portions of the base layer 100 exposed by openings of the reinforcing layer 200′ having the pattern and the first and second silicon nitride layers 105a′ and 105b′ may be etched and removed.

In an embodiment, by removing unnecessary portions of the base layer 100, a mask MSb may be finally completed. The mask MSb shown in FIG. 6K may be an embodiment of the mask MS shown in FIG. 4.

In an embodiment and referring to FIG. 6K, a reinforcing layer 200′ may be formed on the first silicon nitride layer 105a′, which is a thin film forming a pattern of the mask MSb. Since the brittleness of the reinforcing layer 200′ is lower than the brittleness of the first silicon nitride layer 105a′, the durability of the mask MSb for manufacturing a high-resolution display panel can be improved. Meanwhile, embodiments of the reinforcing layer 200′ formed on the first silicon nitride layer 105a′ will be described with reference to FIGS. 7A and 7B.

FIGS. 7A and 7B are diagrams illustrating examples of an embodiment of an area A in FIG. 6K in more detail.

In an embodiment and referring to FIG. 7A, the reinforcing layer 200′ formed on the first silicon nitride layer 105a′ is shown. As described above, the pattern of the reinforcing layer 200′ may be substantially the same as the pattern of the first silicon nitride layer 105a′. However, in this case, it may be disadvantageous to apply a fine process when manufacturing the display panel. According to an embodiment, the dimension of the opening defined by the pattern of the reinforcing layer 200′ may be larger than the dimension of the opening defined by the pattern of the first silicon nitride layer 105a′. As shown in FIG. 7A, a first direction length d2 of the opening defined by the pattern of the reinforcing layer 200′ may be greater than a first direction length d1 of the opening defined by the pattern of the first silicon nitride layer 105a′. Accordingly, even if the thickness of a pattern area of the mask MSb increases by additionally forming the reinforcing layer 200′ on the first silicon nitride layer 105a′, a fine pattern can be formed on a high-resolution display panel.

In an embodiment and referring to FIG. 7B, another embodiment of the reinforcing layer 200′ formed on the first silicon nitride layer 105a′ is shown. In order to form a fine pattern on a high-resolution display panel even if the thickness of the pattern area of the mask MSb increases by additionally forming the reinforcing layer 200′ on the first silicon nitride layer 105a′, the angle between the inner surface of the opening defined by the pattern of the reinforcing layer 200′ and the lower surface of the reinforcing layer 200′ may be smaller than the angle between the inner surface of the opening defined by the pattern of the first silicon nitride layer 105a′ and the lower surface of the first silicon nitride layer 105a′.

Specifically, in FIG. 7B, the angle between the inner surface of the opening defined by the pattern of the first silicon nitride layer 105a′ and the lower surface of the first silicon nitride layer 105a′ is shown to be about 90 degrees. In addition, in FIG. 7B, the angle between the inner surface of the opening defined by the pattern of the reinforcing layer 200′ and the lower surface of the reinforcing layer 200′ is less than about 90 degrees. For example, the angle between the inner surface of the opening defined by the pattern of the reinforcing layer 200′ and the lower surface of the reinforcing layer 200′ may have a value which ranges between about 75 degrees and about 85 degrees.

As described above, according to an embodiment, the reinforcing layer 200′ may be formed so that the angle between the inner surface of the opening defined by the pattern of the reinforcing layer 200′ and the lower surface of the reinforcing layer 200′ is smaller than the angle between the inner surface of the opening defined by the pattern of the first silicon nitride layer 105a′ and the lower surface of the first silicon nitride layer 105a′. Accordingly, even if the thickness of the pattern area of the mask MSb increases by additionally forming the reinforcing layer 200′ on the first silicon nitride layer 105a′, a fine pattern can be formed on a high-resolution display panel.

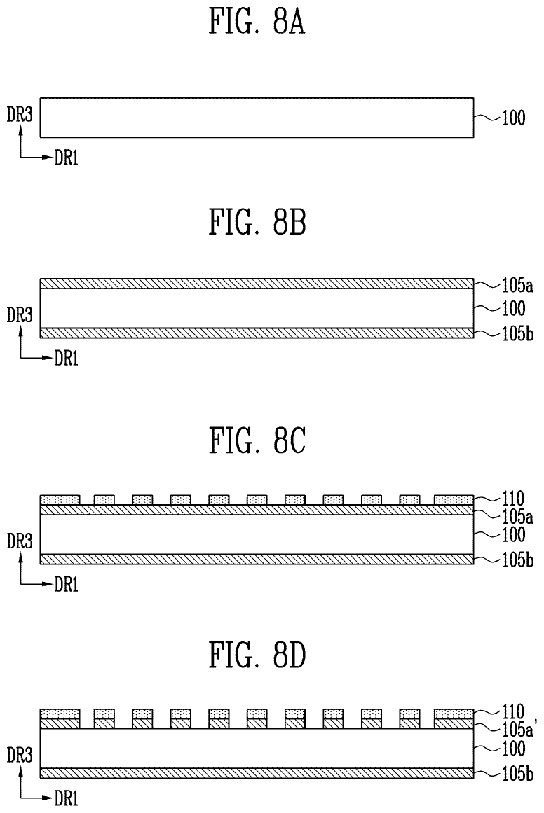

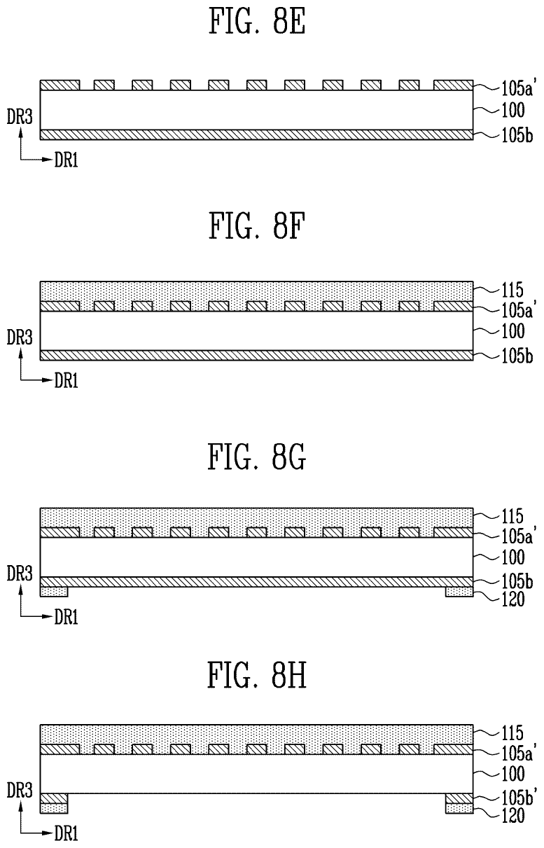

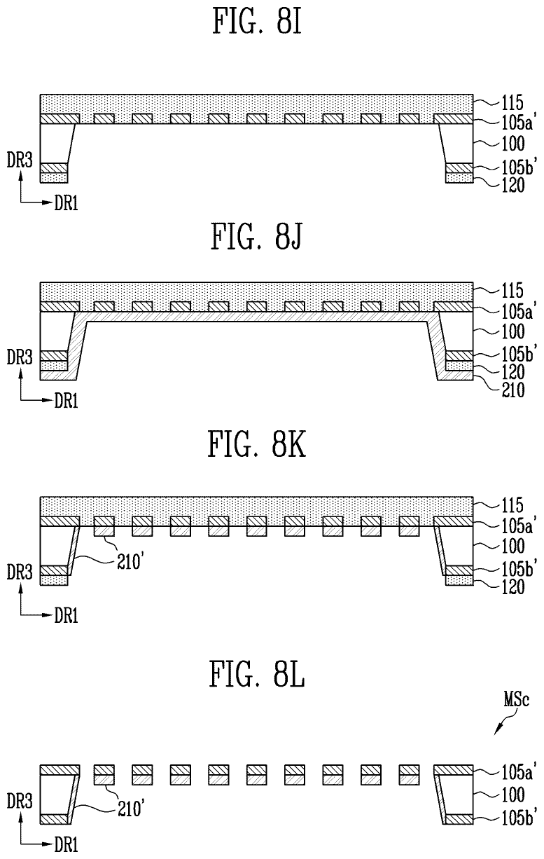

In an embodiment and referring to FIGS. 6A to 7B, an embodiment in which the reinforcing layer 200′ is formed on the upper surface of the first silicon nitride layer 105a′ is shown. However, the invention is not limited thereto, and in another embodiment, the reinforcing layer may be formed on the lower surface of the first silicon nitride layer. This will be described below with reference to FIGS. 8A to 8L.

FIGS. 8A to 8L are cross-sectional views illustrating a process for manufacturing a mask, according to still another embodiment.

In an embodiment and referring to FIG. 8A and FIG. 8B, a base layer 100 may be provided for manufacturing a mask MS. Referring to FIG. 8B, a first silicon nitride layer 105a may be formed on an upper surface of the base layer 100, and a second silicon nitride layer 105b may be formed on a lower surface of the base layer 100. In an embodiment and referring to FIG. 8C, a photosensitive layer 110 may be formed on the first silicon nitride layer 105a. Thereafter, an etching process may be performed on the first silicon nitride layer 105a of FIG. 8C. Through the etching process, a pattern corresponding to the pattern of the photosensitive layer 110 may be formed on the first silicon nitride layer 105a. In an embodiment and referring to FIG. 8D, a first silicon nitride layer 105a′ having a pattern through the etching process is shown. In an embodiment, a dry etching process may be applied to form a fine pattern. In an embodiment and referring to FIG. 8E, the photosensitive layer 110 on the first silicon nitride layer 105a′ having the pattern may be removed. Accordingly, the first silicon nitride layer 105a′ having the pattern may be exposed. In an embodiment and referring to FIG. 8F, a protective layer 115 may be formed on the first silicon nitride layer 105a′ having the pattern. In an embodiment and referring to FIG. 8G, a photosensitive layer 120 may be formed under the second silicon nitride layer 105b. Thereafter, an etching process may be performed on the second silicon nitride layer 105b of FIG. 8G. Through the etching process, a pattern corresponding to the pattern of the photosensitive layer 120 may be formed on the second silicon nitride layer 105b. In an embodiment and referring to FIG. 8H, a second silicon nitride layer 105b′ having a pattern through the etching process is shown. The processes shown in FIGS. 8A to 8H may be substantially the same as the processes shown in FIGS. 5A to 5H.

In an embodiment and referring to FIG. 8I, unnecessary portions of the base layer 100 may be removed. That is, portions of the base layer 100 exposed by openings of the first and second silicon nitride layer 105a′ and 105b′ having patterns may be etched and removed.

In an embodiment and referring to FIG. 8J, a reinforcing layer 210 may be formed on lower surfaces of the protective layer 115 and the first silicon nitride layer 105a′. As described above, the reinforcing layer 210 may include photosensitive polyimide (PSPI). Meanwhile, the reinforcing layer 210 may also be formed on a lower surface of the photosensitive layer 120 and side surfaces of the second silicon nitride layer 105b′ and the base layer 100.

Thereafter, in an embodiment, a reinforcing layer 210′ having a pattern as shown in FIG. 8K may be formed by selectively etching the reinforcing layer 210 using a photolithography process. When the reinforcing layer 210 is composed of photosensitive polyimide, a process of curing the reinforcing layer 210′ having the pattern may be selectively performed.

Thereafter, in an embodiment and referring to FIG. 8L, the photosensitive layer 120 under the second silicon nitride layer 105b′ having the pattern may be removed. In an embodiment, the photosensitive layer 120 may be removed using a developer. Accordingly, the second silicon nitride layer 105b′ having the pattern may be exposed. Meanwhile, in this process, the protective layer 115 on the first silicon nitride layer 105a′ having the pattern may be removed. Accordingly, the first silicon nitride layer 105a′ having the pattern and the reinforcing layer 200′ may be exposed. A mask MSc manufactured as described above may include the reinforcing layer 210′ formed on the lower surface of the first silicon nitride layer 105a′.

In an embodiment, in the mask MSc shown in FIG. 8L, the reinforcement layer 210′ may be formed on the lower surface of the first silicon nitride layer 105a′ within the opening defined by the base layer 100.

Similar to that described above with reference to FIG. 7A, in an embodiment, a dimension of the opening defined by the pattern of the reinforcing layer 210′ formed under the first silicon nitride layer 105a′ may be larger than a dimension of the opening defined by the pattern of the first silicon nitride layer 105a′. Accordingly, even if the thickness of a pattern area of the mask MSc increases by additionally forming the reinforcing layer 210′ under the first silicon nitride layer 105a′, a fine pattern can be formed on a high-resolution display panel.

In another embodiment, similarly to that described above with reference to FIG. 7B, an angle between an inner surface of the opening defined by the pattern of the reinforcing layer 210′ formed under the first silicon nitride layer 105a′ and an upper surface of the reinforcing layer 210′ may be smaller than an angle between an inner surface of the opening defined by the pattern of the first silicon nitride layer 105a′ and the lower surface of the first silicon nitride layer 105a′.

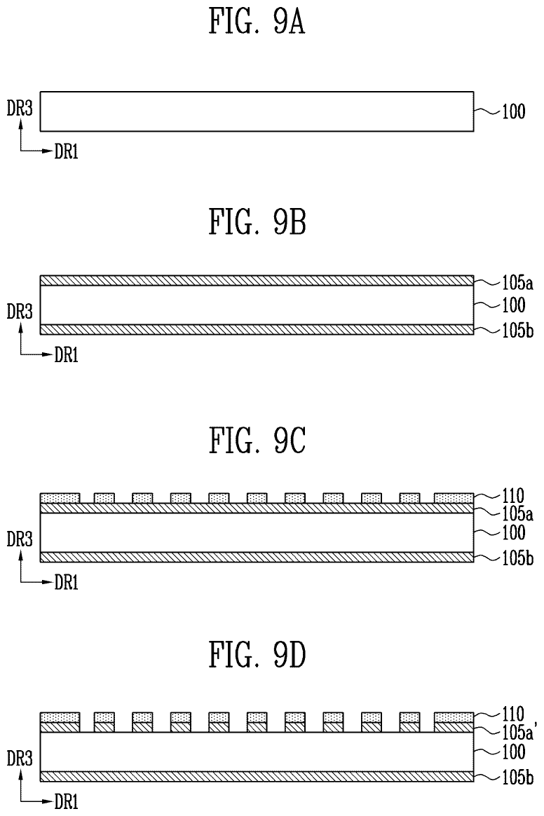

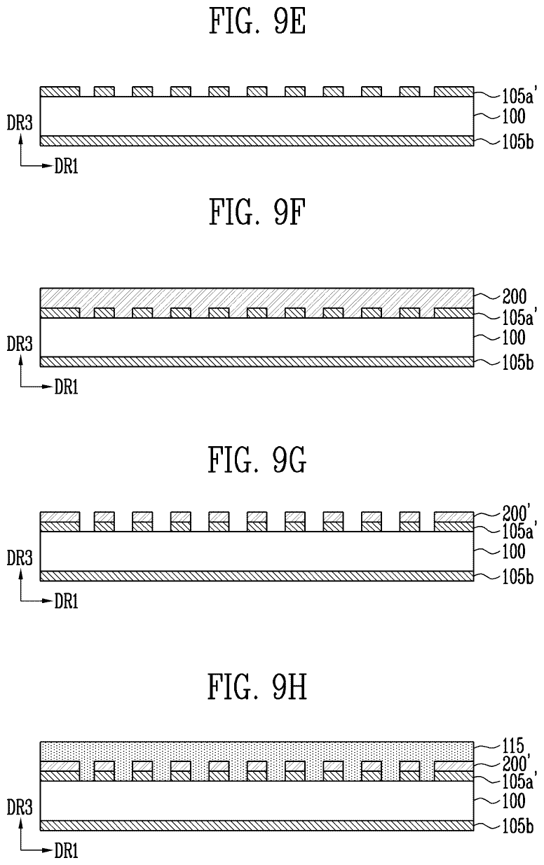

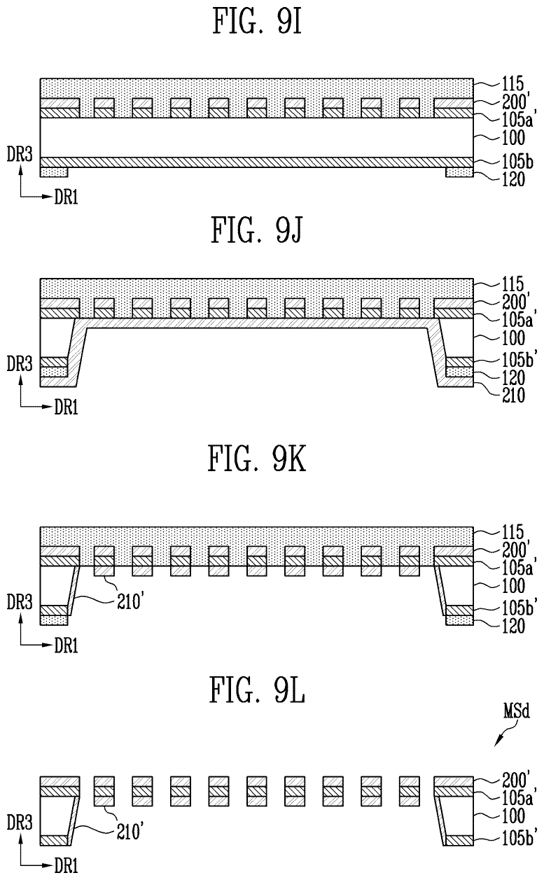

FIGS. 9A to 9L are cross-sectional views illustrating a process for manufacturing a mask, according to still another embodiment.

In an embodiment and referring to FIG. 9A and FIG. 9B, a base layer 100 may be provided for manufacturing a mask MS. Referring to FIG. 9B, a first silicon nitride layer 105a may be formed on an upper surface of the base layer 100, and a second silicon nitride layer 105b may be formed on a lower surface of the base layer 100. In an embodiment and referring to FIG. 9C, a photosensitive layer 110 may be formed on the first silicon nitride layer 105a. Thereafter, an etching process may be performed on the first silicon nitride layer 105a of FIG. 9C. Through the etching process, a pattern corresponding to the pattern of the photosensitive layer 110 may be formed on the first silicon nitride layer 105a. In an embodiment and referring to FIG. 9D, a first silicon nitride layer 105a′ having a pattern through the etching process is shown. In an embodiment and referring to FIG. 9E, the photosensitive layer 110 on the first silicon nitride layer 105a′ having the pattern may be removed. Accordingly, the first silicon nitride layer 105a′ having the pattern may be exposed.

In an embodiment and referring to FIG. 9F, a reinforcing layer 200 may be formed on the first silicon nitride layer 105a′ having the pattern. Thereafter, a reinforcing layer 200′ having a pattern as shown in FIG. 9G may be formed by selectively etching the reinforcing layer 200 using a photolithography process.

Thereafter, in an embodiment and referring to FIG. 9H, a protective layer 115 may be formed on the first silicon nitride layer 105a′ and the reinforcing layer 200′. In an embodiment and referring to FIG. 9I, a photosensitive layer 120 may be formed under the second silicon nitride layer 105b. As described above, the photosensitive layer 120 of FIG. 9I may be formed to have a pattern corresponding to an edge of the mask MS.

In an embodiment and referring to FIG. 9J, unnecessary portions of the base layer 100 may be removed, and a reinforcing layer 210 may be formed on lower surfaces of the protective layer 115 and the first silicon nitride layer 105a′. Meanwhile, the reinforcing layer 210 may also be formed on a lower surface of the photosensitive layer 120 and side surfaces of the second silicon nitride layer 105b′ and the base layer 100.

Thereafter, in an embodiment, a reinforcing layer 210′ having a pattern as shown in FIG. 9K may be formed by selectively etching the reinforcing layer 210 using a photolithography process. When the reinforcing layer 210 is composed of photosensitive polyimide, a process of curing the reinforcing layer 210′ having the pattern may be selectively performed.

Thereafter, in an embodiment and referring to FIG. 9L, the photosensitive layer 120 under the second silicon nitride layer 105b′ having the pattern may be removed. In an embodiment, the photosensitive layer 120 may be removed using a developer. Accordingly, the second silicon nitride layer 105b′ having the pattern may be exposed. Meanwhile, in this process, the protective layer 115 on the first silicon nitride layer 105a′ having the pattern and the reinforcing layer 200′ may be removed. Accordingly, the first silicon nitride layer 105a′ having the pattern and the reinforcing layers 200′ and 210′ may be exposed. A mask MSd manufactured as described above may include the reinforcing layers 200′ and 210′ formed on the upper and lower surfaces of the first silicon nitride layer 105a′.

The mask, according to an embodiment, may be used in a manufacturing process of a high-resolution display panel and may have enhanced strength.

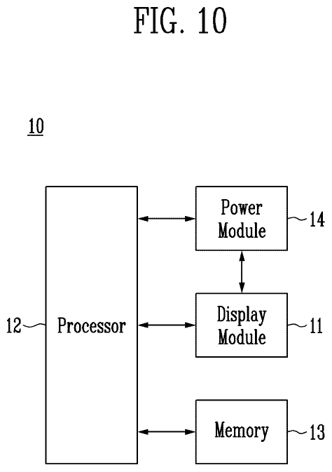

FIG. 10 is a block diagram of an electronic device according to an embodiment. Referring to FIG. 10, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in a display device manufactured using a mask according to embodiments as described above. Specifically, the display panel included in the display module can be manufactured using a mask according to the embodiments described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

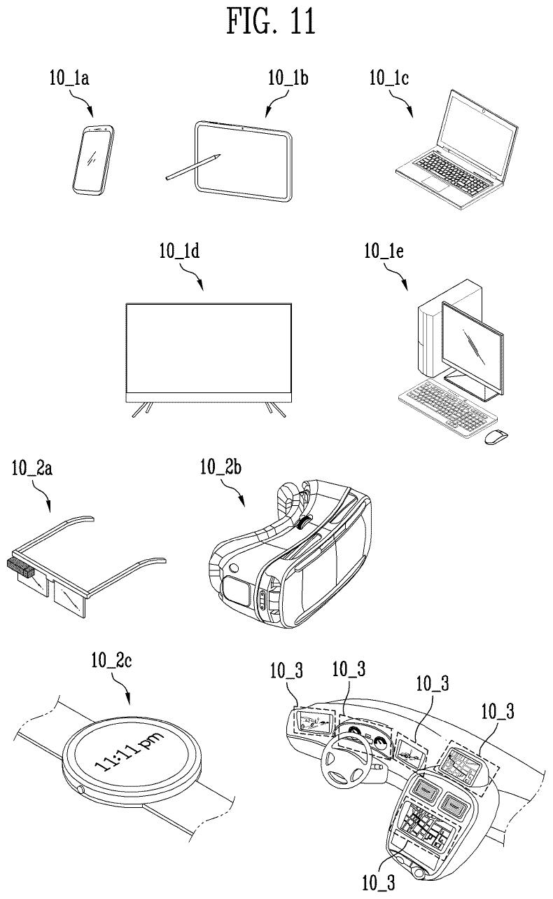

FIG. 11 shows schematic views of various embodiments of an electronic device.

Referring to FIG. 11, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although embodiments of the invention have been described in detail in the detailed description with reference to the drawings, it should be noted that the embodiments described above are intended to illustrate the invention and not to limit the meaning or scope of the invention. Accordingly, those skilled in the art will understand that various modifications and equivalent other embodiments are possible within the scope and spirit of the invention. Example embodiments have been disclosed herein, and although specific terms are employed, they are used and are to be interpreted in a generic and descriptive sense only and not for purpose of limitation. In some instances, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the invention. Thus, while various embodiments have been described above, those skilled in the art will appreciate that various modifications, additions and substitutions are possible, without departing from the scope and spirit of the invention.

What is claimed is:

1. A mask comprising:
a first silicon nitride layer having a first pattern for deposition of a display panel; and
a first reinforcing layer formed on the first silicon nitride layer and having a second pattern corresponding to the first pattern,
wherein a brittleness of the first reinforcing layer is lower than a brittleness of the first silicon nitride layer.

2. The mask of claim 1, further comprising:
a base layer positioned below the first silicon nitride layer and having a third pattern.

3. The mask of claim 2, further comprising:
a second reinforcing layer formed below the first silicon nitride layer and having a fourth pattern corresponding to the first pattern.

4. The mask of claim 3, wherein the second reinforcing layer is formed within an opening of the base layer, wherein the opening of base layer is defined by the third pattern.

5. The mask of claim 2, wherein the base layer includes silicon.

6. The mask of claim 2, further comprising:
a second silicon nitride layer formed below the base layer.

7. The mask of claim 1, wherein the first reinforcing layer includes photosensitive polyimide.

8. The mask of claim 7, wherein the first reinforcing layer is formed by performing a curing process on a photosensitive polyimide layer, wherein the second pattern is formed on the photosensitive polyimide layer.

9. The mask of claim 1, wherein a dimension of an opening defined by the second pattern is larger than a dimension of an opening defined by the first pattern.

10. The mask of claim 1, wherein an angle between an inner surface of the opening defined by the second pattern and a lower surface of the first reinforcing layer is smaller than an angle between an inner surface of the opening defined by the first pattern and a lower surface of the first silicon nitride layer.

11. A mask comprising:
a base layer having a first opening;
a first silicon nitride layer formed on the base layer and having a first pattern for deposition of a display panel; and
a reinforcing layer formed below the first silicon nitride layer within the first opening of the base layer and having a second pattern corresponding to the first pattern,
wherein a brittleness of the reinforcing layer is lower than a brittleness of the first silicon nitride layer.

12. The mask of claim 11, wherein the base layer includes silicon.

13. The mask of claim 11, further comprising:
a second silicon nitride layer formed below the base layer.

14. The mask of claim 1, wherein the reinforcing layer includes photosensitive polyimide.

15. The mask of claim 14, wherein the reinforcing layer is formed by performing a curing process on a photosensitive polyimide layer, wherein the second pattern is formed on the photosensitive polyimide layer.

16. The mask of claim 14, wherein a dimension of an opening defined by the second pattern is larger than a dimension of an opening defined by the first pattern.

17. The mask of claim 11, wherein an angle between an inner surface of the opening defined by the second pattern and an upper surface of the reinforcing layer is smaller than an angle between an inner surface of the opening defined by the first pattern and a lower surface of the first silicon nitride layer.

18. The mask of claim 11, wherein the base layer is positioned below the first silicon nitride layer and includes a third pattern.

19. An electronic device, comprising:
a display device having a display panel which includes a display element, wherein the display element includes functional layers which are formed via a patterning process which uses a mask, wherein the mask comprises,
a first silicon nitride layer having a first pattern for deposition of a display panel; and
a first reinforcing layer formed on the first silicon nitride layer and having a second pattern corresponding to the first pattern,
wherein a brittleness of the first reinforcing layer is lower than a brittleness of the first silicon nitride layer.

20. The electronic device of claim 19, wherein the mask further comprises, a base layer positioned below the first silicon nitride layer and having a third pattern.
